(19) United States
(12) Patent Application Publication
(10) Pub. No.: US 2016/0139212 A1
(43) Pub. Date: May 19, 2016

(54) METHODS AND SYSTEMS FOR POWER RESTORATION PLANNING EMPLOYING SIMULATION AND TRANSIENT TEST ANALYSIS

(71) Applicant: ELEON ENERGY, INC., Austin, TX (US)

(72) Inventors: Chenxi Lin, Norman, OK (US); Xiaosong Yang, Austin, TX (US)

(73) Assignee: ELEON ENERGY, INC., Austin, TX (US)

(21) Appl. No.: 14/541,023

(22) Filed: Nov. 13, 2014

(51) Int. Cl. G01R 31/40; G06F 17/50

(52) U.S. Cl. CPC G01R 31/40; G06F 17/5009

(57) ABSTRACT

A computer system includes at least one processor, and a storage device coupled to at least one processor. The storage devices stores instructions that, when executed, causes the at least one processor to simulate restoration of a power grid system, to perform a transient test for the simulated restoration, and to generate a restoration plan for the power grid system based on the simulation and transient test results.

### BACKGROUND

Power system restoration planning tools become more important daily due to the significant amount of uncertainties and risks from integrated variable renewable energy resources, market activities and stressed power system facilities. Typically, restoration planning is an off-line process ensuring an effective coordinated restoration following a wide-area blackout. Due to the size and complexity of the problem, conventional planning tools rely on a number of manual studies based on certain selected load scenarios, size-reduced network models and fixed generation profiles. Conventional planning tools may not be adequate for the future smart-grid with frequent system reconfigurations, variable energy resources and responsive loads.

One of the deficiencies of existing power system restoration planning tools is that transient voltage or current surges are not adequately accounted for. These transient surges correspond to fast oscillation waves due to sudden changes of energy magnitudes in electric, magnetic or mechanical forms (e.g., due to switching activities undertaken for reconfiguration of a power grid during restoration and islanding operations). Although the durations of transient surges are typically very short, ranging from a few microseconds to many seconds, the amplitudes usually are very high, which may damage sensitive electronics and isolations, lead to device faults or even system failures.

Accurately assessing transient surges is a significant challenge due to several factors. One factor is the amount of information needed. Such information may include the structure of the power grid, the status of individual components, protection scheme settings, fault locations, and even the weather. Further, different sets of assumption and assessment methods may be needed to account for system damping conditions, grid operating modes, and different stages of restoration. Further, operations involving transmission branches, generators, and loads are often handled by different personnel, departments, or entities. Further, various unknowns or randomized scenarios are possible (e.g., energy residuals in the power equipment, switching phase angles, device status, and weather conditions). Again, existing power system restoration planning tools do not adequately account for transient surges.

### BRIEF DESCRIPTION OF THE DRAWINGS

Accordingly, there are disclosed herein methods and systems for power restoration planning employing simulation and transient test analysis. In the drawings:

FIG. 1 is a block diagram showing an overview of an illustrative power restoration planning environment;

FIG. 2 is a block diagram showing an illustrative computer system with a power restoration simulation application;

FIGS. 3A-3C are schematic diagrams showing various steady-state analysis circuit models;

FIGS. 4A-4H are schematic diagrams showing various transient analysis circuit models.

FIG. 5 is a flowchart showing a transient validation method for power restoration planning;

FIG. 6 is a schematic diagram showing coupled systems separated into subsystems;

FIG. 7 is a chart showing a linear interpolation scheme;

FIGS. 8A-8H are illustrative screenshots corresponding to power restoration simulation software with a transient test function;

FIG. 9 is a flowchart showing an illustrative power restoration planning method; and

FIG. 10 is a block diagram showing illustrative computer system components.

It should be understood, however, that the specific embodiments given in the drawings and detailed description thereto do not limit the disclosure. On the contrary, they provide the foundation for one of ordinary skill to discern the alternative forms, equivalents, and modifications that are encompassed together with one or more of the given embodiments in the scope of the appended claims.

### NOTATION AND NOMENCLATURE

Certain terms are used throughout the following description and claims to refer to particular system components. As one skilled in the art will appreciate, individuals and organizations may refer to a component by different names. This document does not intend to distinguish between components that differ in name but not function. In the following discussion and in the claims, the terms “including” and “comprising” are used in an open-ended fashion, and thus should be interpreted to mean “including, but not limited to . . . ” Also, the term “couple” or “couples” is intended to mean either an indirect, direct, optical or wireless electrical connection. Thus, if a first device couples to a second device, that connection may be through a direct electrical connection, through an indirect electrical connection via other devices and connections, through an optical electrical connection, or through a wireless electrical connection.

### DETAILED DESCRIPTION

The following discussion is directed to computer-based power restoration planning tools, including power restoration simulation and a transient test function. In at least some embodiments, power restoration simulation and planning software is executed by one or more computers. As an example, a computer executing power restoration simulation and planning software may be part of or may be in communication with an electrical grid control system. In such case, results of a power restoration simulation, including transient test results, may be used to program or otherwise select options for power restoration of an electrical grid in the event of a power outage.

In at least some embodiments, power restoration simulation and planning software features may be available via a website. For example, a client-server system may be provided to enable an electrical grid entity or service provider to download or access power restoration simulation and planning software. In one example client-server system scenario, a server computer receives a request from a client computer. The request includes or enables a transfer of information related to a particular electrical grid and power restoration scenario. With the information corresponding to the particular scenario, the server computer is able to process the request and simulate power restoration. As part of the power restoration simulation, a transient test function is performed. Once completed, the server computer sends simulation results, including transient test results, back to the client computer. The simulation results may include, for example, a restoration plan along with relevant test information such as transient test warnings and related voltage or current values. An electrical grid entity or service provider may use the simulation results to make decisions or plans for restoring power to an electrical grid after a power outage. Further, the simulation results may guide electrical grid modifications performed by electrical grid entity or service provider. Example electrical grid modifications include adding components (e.g., generators, loads, shunts, branches, or buses), removing components, and/or providing different connection options between components.

It should be appreciated that the power restoration simulation operations described herein, including the transient test function, may be performed by one or more computers. Such computers may be stand-alone computers, networked computers, and/or computers in a client-server relationship. To execute power restoration simulation software, a computer receives and installs a copy of the software (via download or other distribution). Once installed, the power restoration simulation software enables some or all functions, including the transient test function described herein. An example power restoration simulation software version provides a user interface that enables an end-user to select or provide a file that describes a particular electrical grid and power restoration scenario. Alternatively, electrical grid and power restoration scenario details may be selected from a menu of options. The user interface also enables an end-user to select test options, including transient test options. The test results for the particular power restoration simulation may be displayed via a computer monitor and/or a related report (a file or printout) is generated for storage or later analysis. As desired, different electrical grid and power restoration scenarios can be created and tested. The results of different scenarios can be compared and used to guide power restoration and/or electrical grid planning operations of an electrical grid entity or service provider.

In at least some embodiments, the disclosed power restoration simulation and planning software involves four steps: 1) sectionalization; 2) generator restoration; 3) load restoration; 4) and synchronization. For more information regarding power restoration simulation including the above steps, reference may be had to U.S. Pat. App. Pub. No. 2013/0346057 A1, entitled “Methods and Systems for Power Restoration Planning” and filed Jun. 26, 2012. The disclosed transient test functions described herein are applicable, in at least some embodiments, to corresponding load restoration and/or synchronization steps of a power restoration simulation process.

As a specific example, a transient test function may involve three steps: initialization, transient model creation, and transient model deployment. In the initialization step, the initial conditions for grid structure and the status of grid components are determined. The inputs for initialization are system topology, outputs of on-line generators and loads. In at least some embodiments, the system topology is obtained from values in a grid topology file. An example topology includes five types of devices: buses, generators, loads, shunts (capacitor and inductor), and branches (transmission line and transformer). The output of the initialization step is the voltage at each bus and current in each branch before switching.

In the transient model creation step, transient models are created to represent connecting a new branch to an already energized system. In at least some embodiments, a transient model may include transient resistances and current sources with dependency on previous states. For example, the previous state may correspond to steady-state analysis results. Transient models may also account for other factors, such as voltage dependence in surge arrester and loads.

In the transient model deployment step, electromagnetic transients are calculated based on one or more transient models. For example, calculating electromagnetic transients may involve consideration of the operating modes for the generators and loads. Further, the amplitudes, durations and locations of voltage and/or current surges for the particular simulated scenario are analyzed in this process. In at least some embodiments, electromagnetic transient calculations using transient models as described herein includes applying assumptions and/or simplifications to improve the efficiency of calculating electromagnetic transients.

In at least some embodiments, a user interface enables an end-user to select transient test options. As an example, an end-user may select from worst-case and statistical switching options. Worst case switching corresponds to a quick transient validation of a restoration plan, while statistical switching provides detailed information of transient values calculated for each of multiple iterations of a transient test. Various other transient test options for a power restoration simulation are described herein. Once transient test options are selected (e.g., by default or user selection), the transient test operations may be performed automatically as part of a power restoration simulation process.

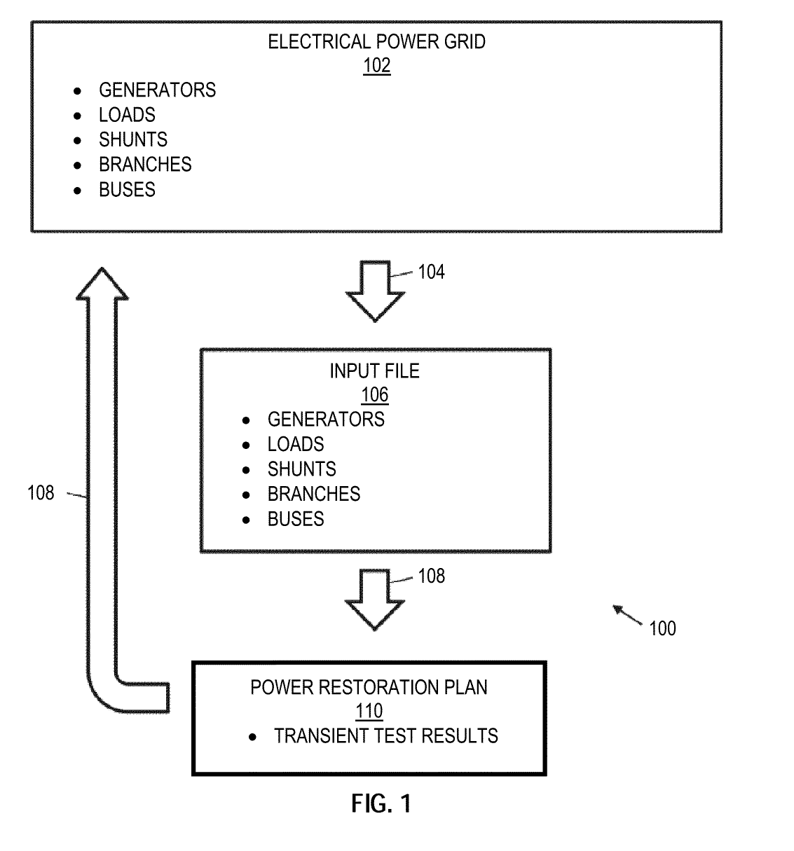

FIG. 1 illustrates a power restoration planning environment 100 in accordance with an embodiment of the disclosure. As shown, the environment 100 comprises an electronic power grid 102 comprising generators, loads, shunts, branches, and/or buses. A translation step 104 is applied to prepare an input file 106 that represents the electrical power grid 102. For example, the input file 106 may comprise a list or table of generators, loads, shunts, branches, and/or buses and their respective parameters in accordance with the components of the electrical power grid 102. In at least some embodiments, the translation step 104 involves entering data to describe an electrical power grid topology using software that may or may not be part of the power restoration and planning software described herein. A power restoration simulation step 108, including a transient test function, is then applied to the electrical power grid topology represented by the input file 106 to determine a power restoration plan 110. The power restoration plan 110 may be applied at step 112 to restore power to the electrical power grid 102. In some embodiments, the power restoration plan 110 is generated in response to a power outage. Alternatively, the power restoration plan 110 is generated before a power outage for use in restoring power to the electrical power grid 102 when needed.

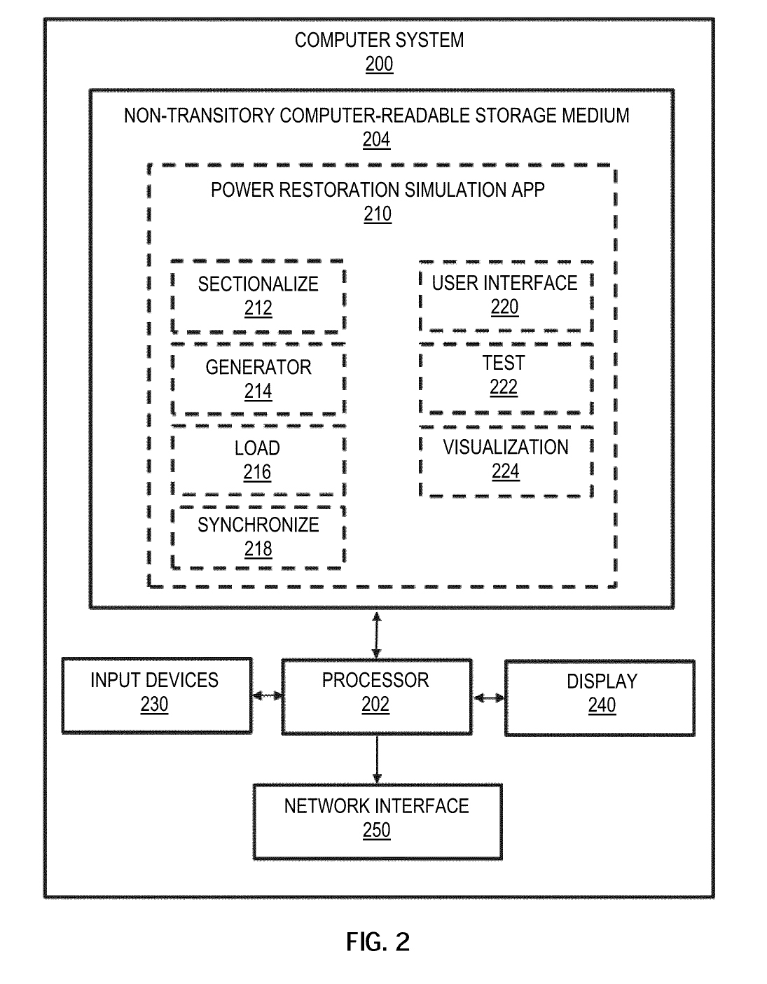

FIG. 2 illustrates a computer system 200 in accordance with an embodiment of the disclosure. The computer system 200 may correspond to, for example, a computer in the form of a mobile device, a tablet computer, a laptop computer, a desktop computer, or a server computer. As shown, the computer system 200 comprises a processor 202 coupled to a non-transitory computer readable storage 204 storing a power restoration simulation application 210. The computer system 200 may also comprise a network interface 250 coupled to the processor 202. Further, in at least some embodiments, the computer system 200 comprises input devices 230 and a display 240 coupled to the processor 202.

The processor 202 of the computer system 200 is configured to execute instructions stored by the non-transitory computer readable storage 204. The processor 202 may be, for example, a general-purpose processor, a digital signal processor, a microcontroller, etc. Processor architectures generally include execution units (e.g., fixed point, floating point, integer, etc.), storage (e.g., registers, memory, etc.), instruction decoding, peripherals (e.g., interrupt controllers, timers, direct memory access controllers, etc.), input/output systems (e.g., serial ports, parallel ports, etc.) and various other components and sub-systems. In operation, the processor 202 executes instructions, codes, computer programs, scripts which it accesses from hard disk, floppy disk, optical disk (these various disk based systems may all be considered secondary storage), read-only memory (ROM), random access memory (RAM), the network interface 250, or the input devices 230. While only one processor 202 is shown, multiple processors may be present. Thus, while instructions may be discussed as executed by a processor, the instructions may be executed simultaneously, serially, or otherwise executed by one or multiple processors.

The non-transitory computer readable storage 204 corresponds, for example, to random access memory (RAM), which stores programs and/or data structures during runtime of the computer system 200. For example, during runtime of the computer system 200, the non-transitory computer readable storage 204 may store the power restoration simulation application 210 for execution by the processor 202 to perform the power restoration simulation, including transient test operations as described herein. The power restoration simulation application 210 may be distributed to the computer system 200 via a network connection or via a local storage device corresponding to any combination of non-volatile memories such as semiconductor memory (e.g., flash memory), magnetic storage (e.g., a hard drive, tape drive, etc.), optical storage (e.g., compact disc or digital versatile disc), etc. Regardless the manner in which the power restoration simulation application 210 is distributed to the computer system 200, the code and/or data structures corresponding to the power restoration simulation 210 are loaded into the non-transitory computer readable storage 204 for execution by the processor 202.

The network interface 250 may couple to the processor 202 to enable the processor 202 to communicate with network devices. In different embodiments, the network interface 250 may take the form of modems, modem banks, Ethernet cards, universal serial bus (USB) interface cards, serial interfaces, token ring cards, fiber distributed data interface (FDDI) cards, wireless local area network (WLAN) cards, radio transceiver cards such as code division multiple access (CDMA), global system for mobile communications (GSM), long-term evolution (LTE), worldwide interoperability for microwave access (WiMAX), and/or other air interface protocol radio transceiver cards, and other well-known network devices. The network interface 250 may enable the processor 202 to communicate with the Internet or one or more intranets.

As an example, for a stand-alone computing scenario, the network interface 250 may enable the computer system 200 to download a stand-alone version of the power restoration simulation application 210. Once downloaded, the power restoration simulation application 210 enables stand-alone operations and user-interface options related to performing power restoration simulation and providing corresponding power restoration plans including transient test results. For a client-computing scenario, the network interface 250 may enable the computer system 200 to download a client-side version of the power restoration simulation application 210. Once downloaded, the power restoration simulation application 210 enables client-side operations and user-interface options related to submitting power restoration simulation requests and receiving corresponding power restoration plans including transient test results. Another example of client-side operations may include submitting a request to store or access previously submitted power restoration simulation requests and corresponding power restoration plans with transient test results. For a server-computing scenario, the network interface 250 may enable the computer system 200 to download a server-side version of the power restoration simulation application 210. Once downloaded, the power restoration simulation application 210 enables server-side operations related to receiving power restoration simulation requests and providing corresponding power restoration plans including transient test results. Another example of server-side operations includes providing a power restoration plan with transient test results in response to a request to access results of previously submitted power restoration simulation request.

The input devices 230 may comprise various types of input devices for selection of data or for inputting of data to the computer system 200. As an example, the input devices 230 may correspond to a touch screen, a key pad, a keyboard, a cursor controller, or other input devices. It should be appreciated that input devices 230 need not be included for all computer system variations (e.g., some server embodiments may not include input devices 230). Further, while not shown, it should be appreciated that the computer system 200 may also include output devices such as printers to provide a print-out of power restoration simulation results including transient test results.

In accordance with at least some embodiments, the power restoration simulation application 210 comprises a sectionalize module 212, a generator module 214, a load module 216, and a synchronize module 220 to support power restoration planning as described herein. Further, the power restoration simulation application 210 comprises a user interface 220, a test module 222, and a visualization module 224.

The sectionalize module 212 performs sectionalize operations for a power restoration simulation scenario. The generator module 214 performs generator restoration operations for a power restoration simulation scenario. The load module 216 performs load restoration operations for a power restoration simulation scenario. The synchronize module 218 performs synchronize operations for a power restoration simulation scenario. Further, the user interface 220 enables a user to select an input file or to otherwise provide input parameters for the power restoration simulation application 210. Further, the test module 222 provides power restoration plan testing operations, including the transient test operations described herein. The visualization module 224 operates to display simulation options, power restoration plans, or related data to a user.

In at least some embodiments, the operations of the power restoration simulation application 210 involve an undirected graph G=(N, A) model, where N represents the node set and A represents the arc set. The node set is defined as N={n₁, . . . , nₖ}=G∪L∪X, where G={g₁, . . . , gₘ} is the set of generator buses, L={l₁, . . . , lᵣ} is the set of load buses, and X is the set of other buses without any sources. BSεG is the black-start generator bus set. The arc set is defined as A={(a₁¹,a₂¹), . . . , (a₁^{q},a₂^{q})}=B∪T, where B represents the set of transmission lines and T represents the set of transformers.

The objective function can be formulated to maximize the number of generators in service during power system restoration periods without violating system constraints. In at least some embodiments, three steady-state criteria are used to validate the restoration plan. These criteria are voltage constraint, line flow constraint, and generator output constraint.

Assuming the system has k total buses with m generators and q branches, the restoration problem is the solution for the following Integer Programming (IP) problem.

$$max {\sum }_{t = 1}^{T} ( {\sum }_{i = 1}^{m} {u}_{{g}_{i}}^{t} + {\sum }_{i = 1}^{r} {u}_{{l}_{i}}^{t} + {\sum }_{i = 1}^{q} {u}_{{a}_{i}}^{t} )$$

$$s . t . \{ \begin{matrix}{V}_{{n}_{j}}^{min} \leq {V}_{{n}_{j}}^{t} \leq {V}_{{n}_{j}}^{max} , & j = 1 , … , k \\ {S}_{{a}_{i}}^{t} \leq {S}_{{a}_{i}}^{max} , & i = 1 , … , q \\ {P}_{{g}_{i}}^{min} \leq {P}_{{g}_{i}}^{t} \leq {P}_{{g}_{i}}^{max} , & i = 1 , … , m\end{matrix}$$

where u_{g}_{ᵢ}^{t} uₗ_{ᵢ}^{t} and uₐ_{ᵢ}^{t} are binary decision variables denoted as the status of generator gᵢ at time t, the status of load lᵢ, and the status of branch aᵢ. For example, uₗ^{t}=1 means that generator i is energized at time t and uₗ^{t}=0 means it is off at time t. This formulation also applies to uₗ_{ᵢ}^{t} and uₐ_{ᵢ}^{t}, for loads and branches. Vₙ_{ⱼ}^{t} is the voltage of bus nⱼ at time t, where Vₙ_{ⱼ}^{min} and Vₙ_{ⱼ}^{max} represent the minimum and maximum allowable value of bus voltage respectively; Sₐ_{ᵢ}^{t} is the complex power flow in branch aᵢ at time t and Sₐ_{ᵢ}^{max} is the corresponding power flow limit; P_{g}_{ᵢ}^{t} is the real power output of generator gᵢ at time t, where P_{g}_{ᵢ}^{min} and P_{g}_{ᵢ}^{max} are minimum and maximum real power outputs of generator gᵢ.

In accordance with at least some embodiments, the test module 222 of power restoration simulation application 210 also employs various transient models. For example, to connect a new branch to an already energized system, such transient models are configured with transient resistances and current sources with dependency on previous states. Other factors, such as voltage dependence in surge arrester and loads, may also be considered with the standard circuit representations.

In at least some embodiments, the test module 222 performs transient analysis using transient models and numerical integration substitution (NIS). More specifically, in some embodiments, a trapezoidal integrator is used for NIS operations due to its simplicity, stability and reasonable accuracy in most circumstances. Transient analysis operations performed by the test module 222 also may involve discretization and of system components and later combining discretized components in a solution for the nodal voltages. In such case, branch elements are represented by the relationship which they maintain between branch current and nodal voltage. In at least some embodiments, the test module 222 perform transient analysis using Dommel's method, or any other method, configured to combine system characteristics and the trapezoidal rule into a generalized algorithm which permits accurate simulation of transients in networks involving distributed as well as lumped parameters.

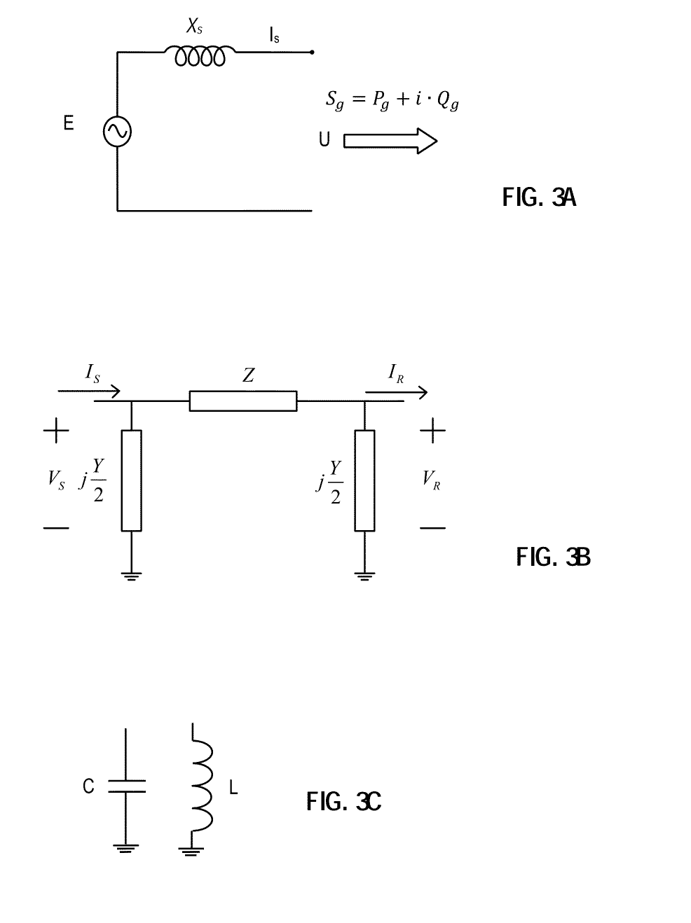

In at least some embodiments, the test module 222 performs transient analysis by using steady-state results as an initial value to transient models. The steady-state results are based, for example, on steady-state models for a generator, a load, a transmission line, and a shunt. An example steady-state model for a generator is represented in FIG. 3A. More specifically, the generator is modeled as an AC voltage source and a series resistance. The generator has real and reactive limits for power flow calculations. Specifically, FIG. 3A represents a steady-state single-phase circuit of a generator, such that:

U=E−XₛIₛ, Equation (1)

where E is the internal voltage (e.g., a function of the excitation current and the rotor rotating speed, whose rms value is obtained from the no-load test of the machine), Xₛ is the synchronous reactance (e.g., obtained from a short-circuit test) to model all the fluxes created by the stator, I is the current delivered by the generator, and U is the voltage at the generator terminals (the output voltage).

The load model is represented as:

$$\begin{matrix}P = {{P}_{0} ( \frac{V}{{V}_{0}} )}^{NP} ( 1 + {K}_{PF} df ) , \\ and & Equation ( 2 ) \\ Q = {{Q}_{0} ( \frac{V }{{V}_{0}} )}^{NQ} ( 1 + {K}_{QF} df ) , & Equation ( 3 )\end{matrix}$$

where P is the equivalent load real power, P₀ is the rated real power per phase, V is the load voltage, V₀ is the rated load voltage, NP is the dP/dV voltage index for real power, K_{PF} is the dP/dF frequency index for real power, Q is the equivalent load reactive power, Q₀ is the rated reactive power per phase, NQ is the dQ/dV voltage index for reactive power, and K_{QF} is the dQ/dF frequency index for reactive power. Equations 2 and 3 represent the load characteristics as a function of voltage magnitude and frequency, where the real and reactive power loads are considered separately. In the steady-state analysis, the index for NP and NQ are equaled to 0, and K_{PF} and K_{QF} are 0 to represent a constant dependent model without frequency dependency.

An example transmission line model is represented in FIG. 3B. For example, to represent a steady-state condition and power flow in a power system, Pᵢ sections may be used for simulation. The transmission line model represented in FIG. 3B is suitable for steady-state analysis of medium and long lines.

To represent shunts during steady-state analysis, a constant impedance element is calculated based on the power and voltage rated conditions such that:

$${X}_{pu} = \frac{{V}_{pu}^{2}}{{Q}_{pu}} , \qquad Equation ( 4 )$$

where Xₚᵤ is the reactance in the reactor per unit (e.g., 1/ωC for a capacitor and ωL for an inductor), Qₚᵤ is the reactor reactive power per unit, and Vₚᵤ is reactor voltage per unit. An example shunt model is represented is FIG. 3C. The shunt model given in equation 4 can be used for both steady-state and transient analysis.

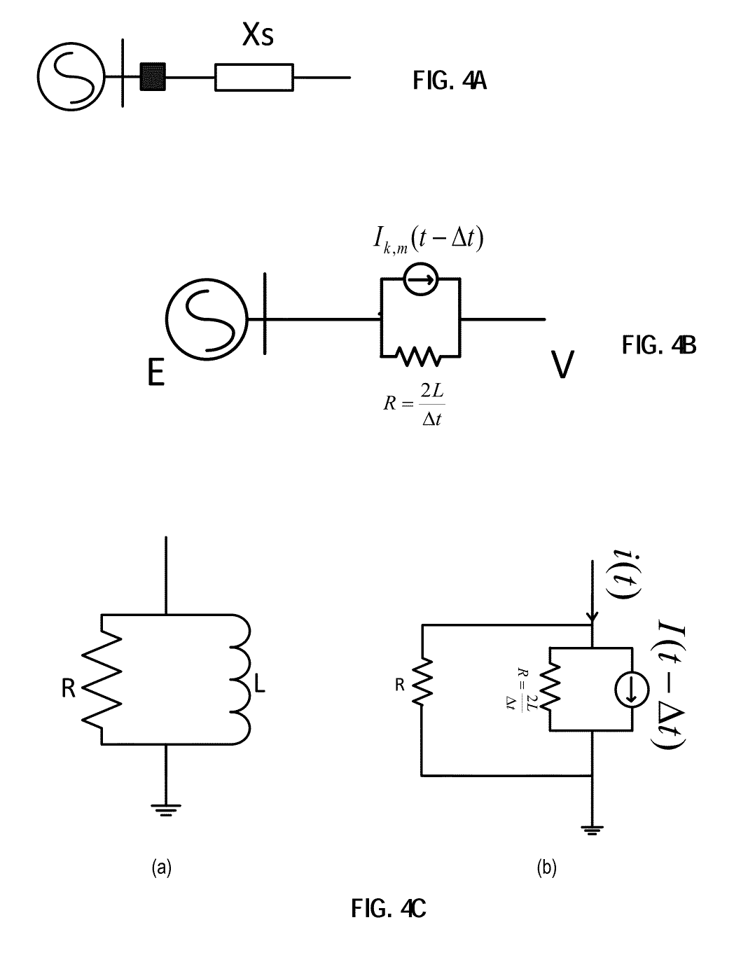

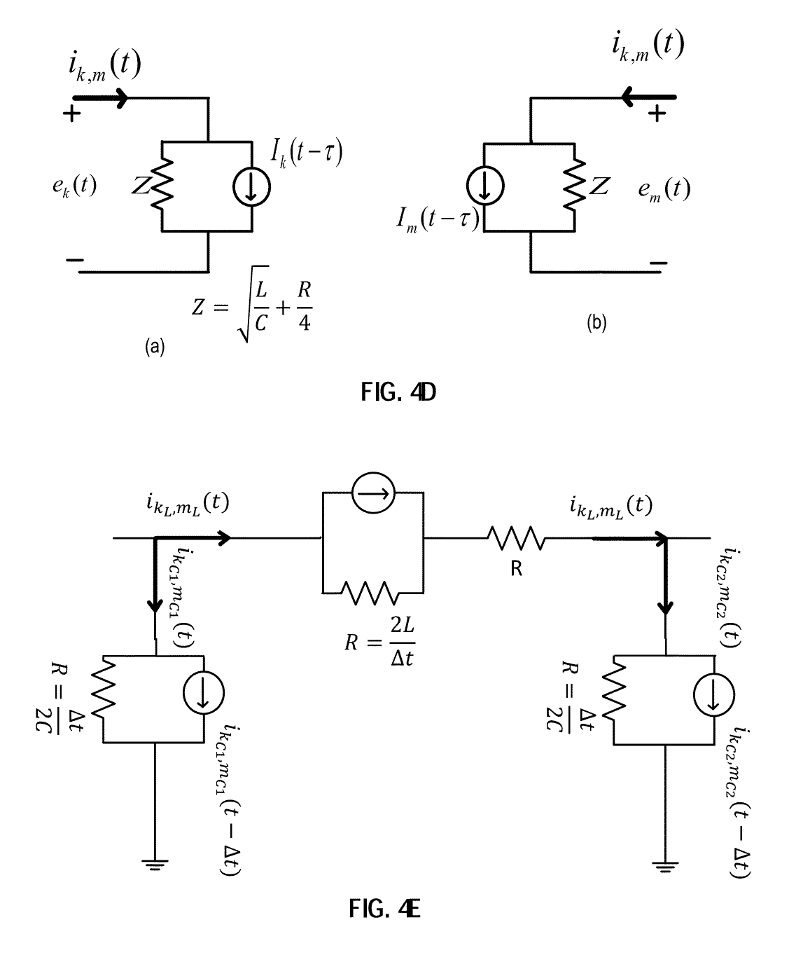

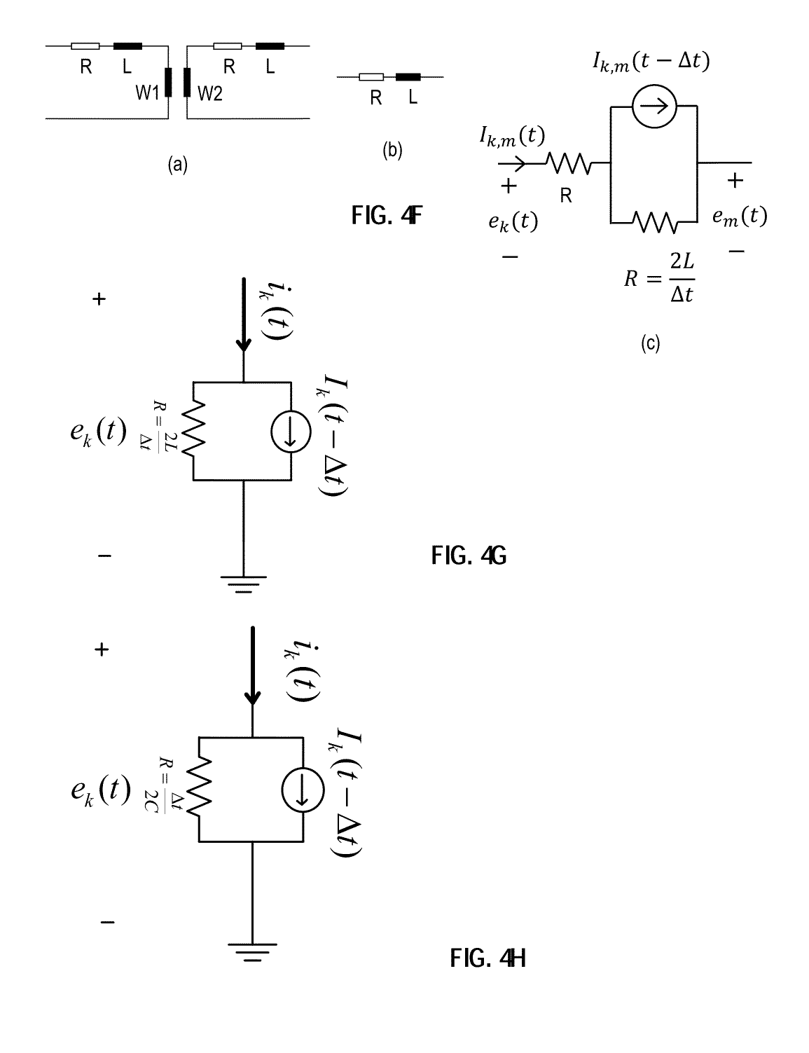

As previously mentioned, the test module 222 performs transient analysis by using steady-state results as an initial value to transient models. Example transient models for a generator, a load, a transmission line, and a shunt are given below. Specifically, FIGS. 4A and 4B represent an example transient model of a generator, such that:

V=E−RI_{R}, Equation (5)

where E is the internal voltage (the RMS value of E can be obtained from no-load test), R is the transient resistance for transient analysis, I_{R} is the current through the transient resistance, and V is the voltage at the generator terminals (the output voltage). The transient generator model of FIGS. 4A and 4B is represented with an ideal sine-wave source in series with a transient impedance. In at least some embodiments, dynamic behavior with frequency range of 50 Hz-20 KHz is considered in the transient analysis (slow mechanical behavior in the generator may be ignored).

An example transient load model is represented in FIG. 4C. For transient analysis, loads are modeled as constant impedance represented by a parallel R-L branch. In at least some embodiments, the transient load impedance R and L in FIG. 4C is calculated by P/V² and Q/V², respectively. The voltage V is obtained based on the steady-state power flow computation in the previous restoration step.

Example transient transmission line models are represented in FIGS. 4D and 4E. For transient analysis, transmission lines are represented differently depending on their length. For example, long transmission lines may be represented using the Bergeron model. Meanwhile, short transmission lines may be represented using general lumped Pᵢ sections. In at least some embodiments, wave travel time τ is compared to a threshold to determine whether a transmission line is modeled as a long line or short line. For example, if the wave travel time is larger than the time step Δt, then the transmission line may be considered as a long transmission line. On the other hand, if the wave travel time is less than Δt, the transmission line may be considered as a short transmission line. For the transient long transmission line model represented in FIG. 4D:

$$τ = \frac{d}{v} = d * \sqrt{LC} ;$$

$$Z = \sqrt{\frac{L}{C}} ;$$

$${i}_{k , m} ( t ) = \frac{{e}_{k} ( t )}{z} + {I}_{k} ( t - τ ) ;$$

$${i}_{m , k} ( t ) = \frac{{e}_{m} ( t )}{Z} + {I}_{m} ( t - τ ) ;$$

$${I}_{k} ( t - τ ) = - {I}_{m} ( t - τ ) - \frac{{e}_{m} ( t - τ )}{Z} ;$$

$$and$$

$${I}_{m} ( t - τ ) = - {I}_{k} ( t - τ ) - \frac{{e}_{k} ( t - τ )}{Z} .$$

For the transient short transmission line model represented in FIG. 4E, the wave travel time is negligible and the transmission line may be represented by using a lumped equivalent of a Pᵢ section.

An example transient transformer model is represented in FIG. 4F. For the transient transformer model represented in FIG. 4F: L is inductance; R is resistance; f is Frequency; w1 is the number of primary transformer turns; w2 is the number of secondary transformer turns. In at least some embodiments, the transient transformer model is based on the following assumptions: 1) the core is not saturated; 2) small winding capacitance; and 3) small mutual capacitance (in the order of μF).

Example transient shunt models are represented in FIGS. 4G and 4H. Shunt elements are modeled by constant impedances for both steady-state power flow simulations and transient states simulations. However, the parameters for steady state simulation will be modified for transient analysis. For reactor absorbing reactive power as in FIG. 4G:

$${X}_{pu} = \frac{{V}_{pu}^{2}}{{Q}_{pu}}$$

$$and$$

$$L = \frac{{X}_{pu}}{ω} = \frac{{X}_{pu}}{120 π} .$$

For capacitor providing reactive power as in FIG. 4H:

$${X}_{pu} = \frac{{V}_{pu}^{2}}{{Q}_{pu}}$$

$$and$$

$$C = \frac{1}{ω {X}_{pu}} = \frac{1}{120 π {X}_{pu}} .$$

Further, a breaker shunt can be modeled as an ideal switch with resistance R→‘∞’ when the breaker is open and R→‘0’ when it is closed. For more information regarding transient load models, transient transmission line models, transient transformer models, and transient shunt models, reference may be had to H. W. Dommel, “Digital computer solution of electromagnetic transients in single- and multiphase networks”, IEEE Transactions on Power Apparatus and Systems, vol. 88, pp. 388-399 (April 1969).

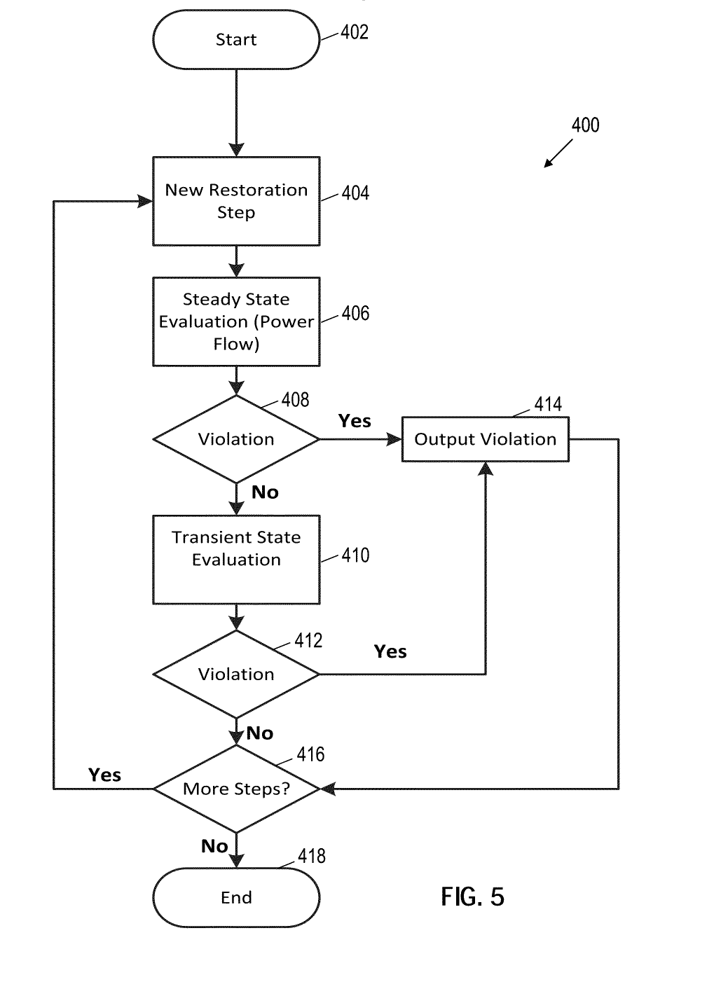

The test module 222 uses the various transient models to represented grid components to be energized, i.e., generators, loads, transmission lines and branches, transformers, breakers, reactors and capacitors. The FIG. 5 shows a power restoration planning method 400 that uses stead-state models and transient models. As shown, the method 400 start at block 402 and proceeds to a new power restoration step at block 404. At block 406, a steady-state evaluation is performed. If a steady-state violation occurs (decision block 408), steady-state violation details are output at block 414. If there is no steady-state violation (decision block 408), a transient-state evaluation is performed at block 410. If a transient-state violation occurs (decision block 412), transient-state violation details are output at block 414. If there is no transient-state violation (decision block 412), the method 400 determines if there are additional power restoration steps at block 416. If so, the method 400 returns to block 404. Otherwise, the method 400 ends at block 418.

In at least some embodiments, the transient-state analysis performed at block 410 includes initialization and nodal analysis stages. During the initialization stage, the initial conditions in structure variables and the status on the grid are determined. For example, the initial status of transient voltages and currents may correspond to steady state results from the power flow in the previous restoration step. This procedure reduces complexity in the models and creates suitable representation for the branches in the case of transmission lines and transformers.

By representing all network components using the transient models as shown in FIGS. 4A-4H, the task of establishing nodal equations for any arbitrary system is simplified. The nodal analysis method accounts for the equilibrium of current injections at each node by using the nodal conductance matrix Y:

$$\begin{matrix}Y = [ \begin{matrix}{Y}_{11} & … & {Y}_{1 n} \\ ⋮ & ⋱ & ⋮ \\ {Y}_{n 1} & … & {Y}_{nn}\end{matrix} ] \\ where \text{:} & Equation ( 6 ) \\ {Y}_{ii} = \{ \begin{matrix}{y}_{ii} + {\sum }_{i \neq j} {y}_{ij} & if i = j \\ - {y}_{ij} & if i \neq j\end{matrix} & Equation ( 7 )\end{matrix}$$

yᵢⱼ is the conductance of all transmission lines going from bus i to bus j. yᵢᵢ is the self-conductance at bus i. The nodal equation that describes the state of the system at time t is:

[Y]e(t)=i(t)+I_{history} Equation (8)

where [Y] is the conductance matrix, e(t) is the vector of nodal voltages, i(t) is the vector of external current sources, and I_{history} is the vector current sources representing past history terms.

In accordance with at least some embodiments, the transient analysis performed by the test module 422 involves calculating the transient voltage e(t) at all buses for different time t. Note that the conductance matrix [Y] is real and symmetric when incorporating network components. As the elements of [Y] are dependent on time step Δt, keeping the time step constant results in a value for [Y] that is constant. Accordingly, a triangular factorization can be performed before entering the time step loop for fast calculation. Moreover, to the extent each node in the power system is connected to only a few other nodes, the conductance matrix is sparse. This property is exploited by only storing non-zero elements and using optimal ordering elimination schemes.

The transient voltage e(t) is also dependent on the closing time of breakers. In at least some embodiments, the transient analysis involves two types of switching method: worst-case switching and statistical switching. Worst case switching refers to the situation in which the switch closes at the voltage peaks. Meanwhile, statistical switching refers to the situation in which the switch closes randomly under a given distribution. In general, worst case switching is much faster than statistical switching. Accordingly, worst case switching may be used for a quick evaluation of a restoration plan while statistical switching is applied to obtain detailed transient test results. In at least some embodiments, the transient analysis provides information regarding the following parameters: bus transient overvoltage, line charging current, transformer overvoltage and charging current, and/or overvoltage and charging current in shunt devices.

Transient analysis for a large scale power system is always a challenging issue. Accordingly, in at least some embodiments, transient analysis for each subsystem is performed instead of the entire system to improve computation efficiency. Specifically, transmission lines in the system introduce decoupling into the conductance matrix. This is because the transmission line model shown in FIG. 4D injects current at one terminal as a function of the voltage at the other terminal at previous time steps. Therefore, in the present time step, there is no dependency on the electrical conditions at the distant terminals of the line. This results in a block diagonal structure of the systems conductance matrix, such that

$$Y = [ \begin{matrix}{Y}_{1} & 0 & 0 \\ 0 & {Y}_{2} & 0 \\ 0 & 0 & {Y}_{3}\end{matrix} ] . \qquad Equation ( 9 )$$

Each decoupled block in this matrix is a subsystem and can be solved by transient analysis at each time step independently of all other subsystems, as the influence from the rest of the system is represented by linearized equivalent sources.

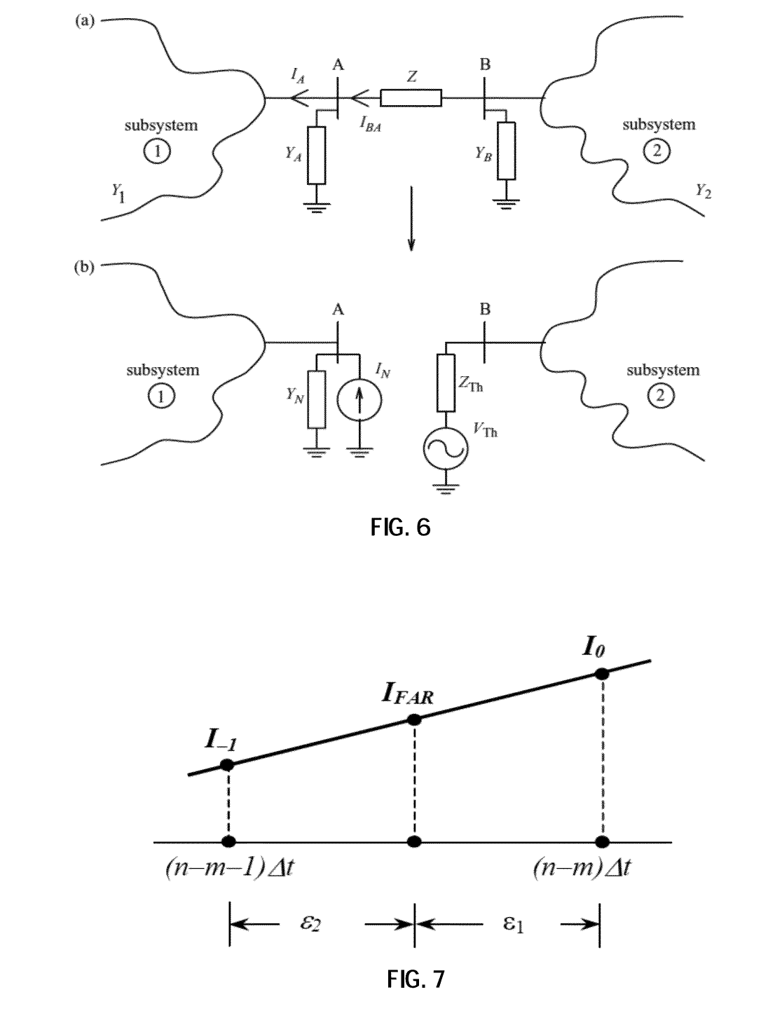

FIG. 6 is a schematic diagram showing coupled systems separated into subsystems. More specifically, part (a) of FIG. 6 represents coupled systems before they are separated into subsystems, and part (b) of FIG. 6 represents the systems after they are separated into subsystems by a linear equivalent. In at least some embodiments, a Norton equivalent may be constructed using information from the previous time step and by looking into subsystem 2 from bus A. The shunt connected at bus A is considered to be part of subsystem 1. For the system represented in FIG. 6, the Norton admittance is given as:

$${Y}_{N} = {Y}_{A} + \frac{( {Y}_{B} + {Y}_{2} )}{Z ( 1 / Z + {Y}_{B} + {Y}_{2} )} . \qquad Equation ( 10 )$$

Further, the Norton current is given as:

I_{N}=I_{A}(t−Δt)+V_{A}(t−Δt)Y_{A}. Equation (11)

Further, the Thevenin impedance is given as:

$${Z}_{Th} = \frac{1}{{Y}_{B}} ( \frac{Z + 1 ( {Y}_{1} + {Y}_{A} )}{Z + 1 / ( {Y}_{1} + {Y}_{A} ) + 1 / {Y}_{B}} ) . \qquad Equation ( 12 )$$

Further, the voltage source is given as:

V_{Th}=V_{B}(t−Δt)+Z_{Th}I_{BA}(t−Δt). Equation (13)

Further, the shunts Y_{N} and Z_{Th} represent the instantaneous response of each subsystem as seen from the interface bus. For more information regarding subsystem analysis for electromagnetic transients, reference may be had to N. Watson and J. Arrillaga, “Power System Electromagnetic Transients Simulation”, London: Institution of Engineering and Technology (2003).

In order to find the transient voltage response caused by switching in system restoration, the entire power system is divided into two subsystems: the area close to the closing breaker and the area far from the closing breaker. Since the area far from the closing breaker has been energized and stabilized in the previous step of restoration, this area is represented by the linearized equivalent source in the transient analysis. On the other hand, the area which is close to the closing breaker is included in the transient analysis.

In at least some embodiments, relative electrical distance (RED) is used to identify the subsystem to be analyzed during transient analysis. Assuming the system has n generators and m buses, then RED is defined as:

R_{m×n}=I_{m×n}−|F_{m×n}|, Equation (14)

where I_{m×n} is a unit matrix with m rows and n columns and F_{m×n} is given by

F_{m×n}=−Y⁻¹_{m×m}Y_{m×n}, Equation (15)

where Y_{m×m} and Y_{m×n} is the corresponding partitioned portions of admittance matrix Y. For each bus j the voltage stability index is given as:

$${I}_{j} = \vert 1 - {\sum }_{i = 1}^{n} {F}_{ji} \frac{{V}_{i}}{{V}_{j}} \vert \qquad Equation ( 16 )$$

where Vᵢ is the voltage of ith generator and Vⱼ is the voltage of jth bus. It can be shown that the stability limit is reached for Iⱼ=1 and the stability margin of the system is obtained as the distance of the maximum I and a unit value, e.g.,

$$( 1 - {max}_{j = 1 , … , m} {I}_{j} ) .$$

Moreover, for a power system with two generators, the voltage stability index for bus j can be rewritten using relative electrical distance as:

$${I}_{j} = \vert {R}_{j 1} ( 1 - \frac{{V}_{2}}{{V}_{j}} ) + {R}_{j 2} ( 1 - \frac{{V}_{1}}{{V}_{j}} ) \vert \qquad Equation ( 17 )$$

where Rⱼ₁ and Rⱼ₂ are the relative electrical distance between bus j and two generators respectively. For more information regarding relative electrical distance, reference may be had to D. Thukaram, “Relative electrical distance concept for evaluation of network reactive power and loss contributions in a deregulated system”, IET Generation, Transmission & Distribution, vol. 3, pp. 1000-1019 (November 2009), and K. Visakha and D. Thukaram, “Transmission charges of power contracts based on relative electrical distances in open access”, Electric Power Systems Research, vol. 70, pp. 153-161 (July 2004).

In at least some embodiments, the procedure for subsystem identification is described as follows. Step 1: Aggregate system into two generator system. One is the generator to be energized and another one is the aggregation of other energized generators called the grid equivalent generator. Step 2: Calculate the RED between each bus and two generators. Step 3: Those buses with small RED to the grid equivalent generator are considered to be closed to the closing breaker and will be analyzed in the transient analysis. Other buses are represented by a linear equivalent source.

Once the two subsystems are found, nodal analysis mentioned above can be applied to calculate the transient voltages. It is shown that the computation effort of transient analysis for a large system is reduced considerably by using linearized equivalent sources. As mentioned above, transient analysis may use the trapezoidal rule in numerical integration method. Although it is simple to implement, stable and fast, it is also susceptible to numerical oscillations when differentiating step changes in voltage or current. There are several solutions can be used to remove numerical oscillation due to the trapezoidal rule such as adding circuit elements, reducing the time step, and/or introducing damping and interpolation. In at least some embodiments, linear interpolation is used to eliminate numerical oscillation in transient analysis.

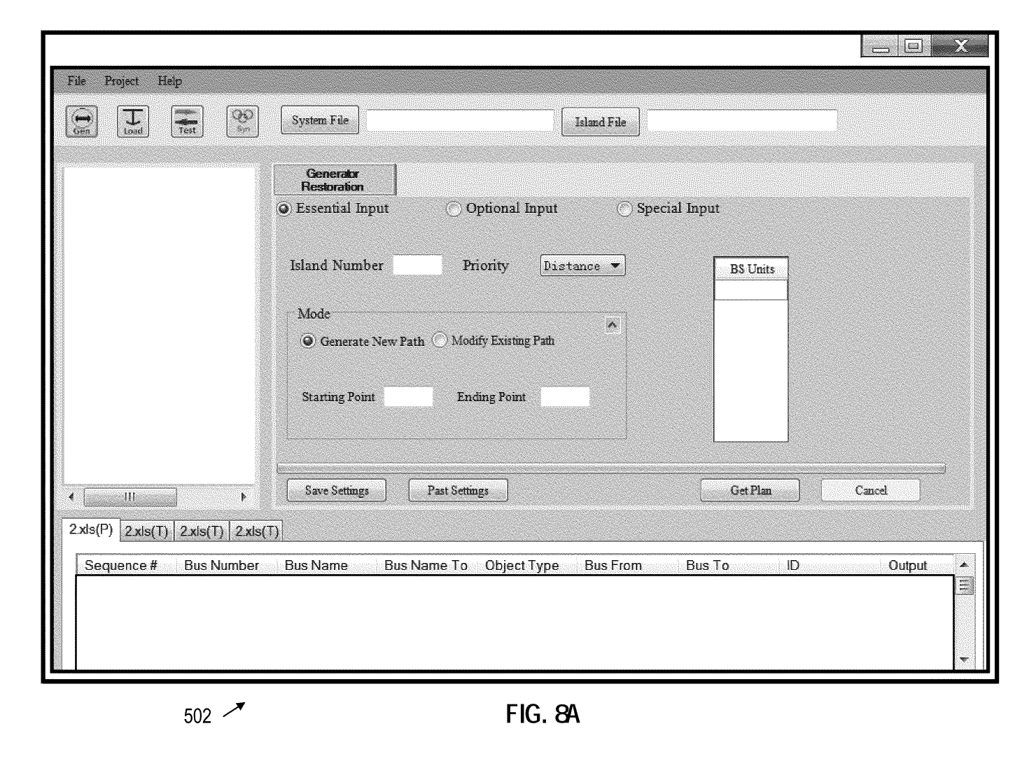

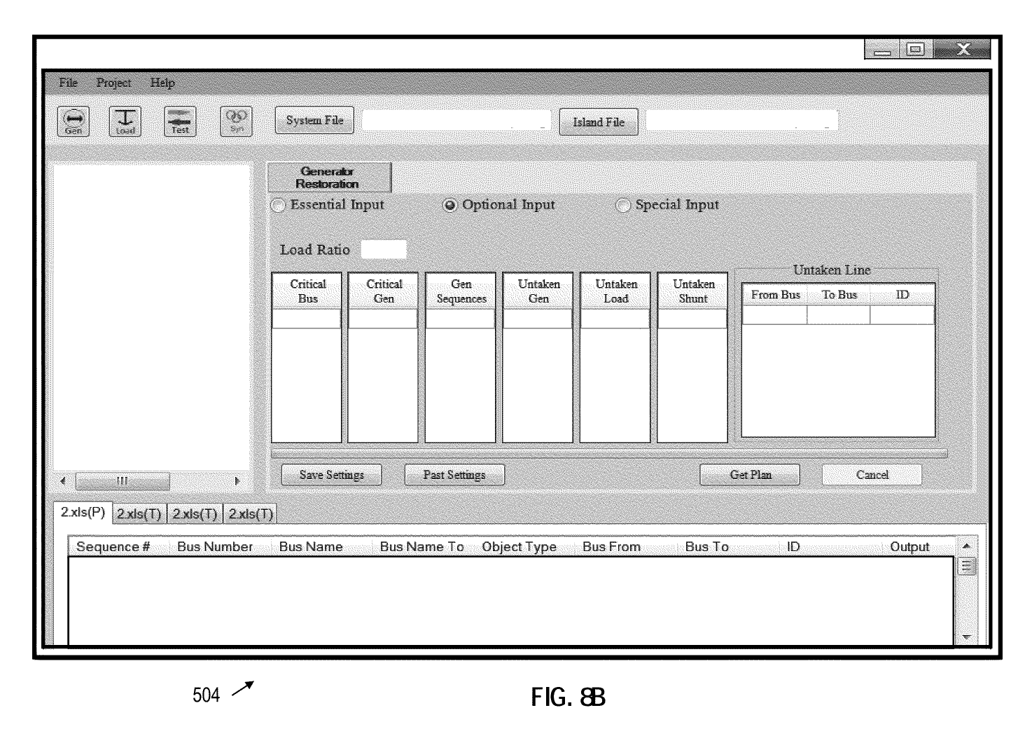

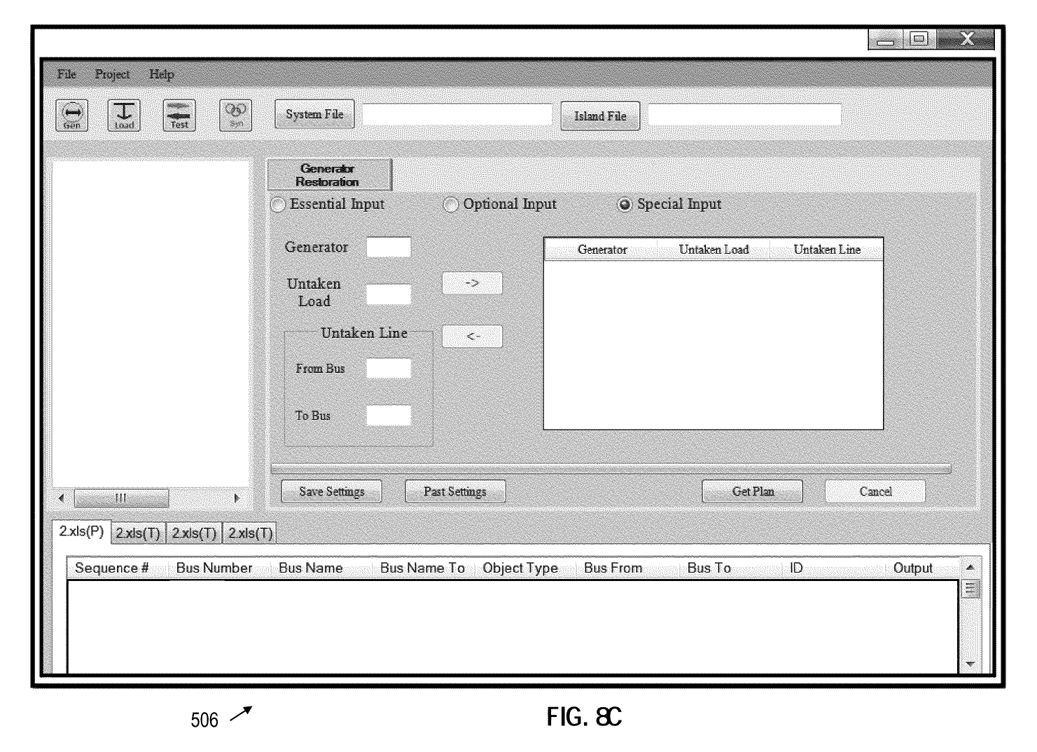

As an example, consider two given values for a line travel time τ and a simulation time step Δt. In such case, τ=mΔt+ε₁ and ε₂=Δt−ε₁, where m is the integer part of τ/Δt and ε₁ is the remainder, smaller than Δt. Further, suppose that the current time at an ongoing simulation is t=nΔt. In such case, i_{FAR}(t−τ)=i_{FAR}((n−m)Δt−ε₁). Using linear interpolation as shown in FIG. 7, the history term in the transient analysis of the transmission line is given by i_{FAR}(t−τ)=a₀I₀+a₁I₋₁, where a₀=ε₂/Δt, α₁=ε₁/Δt, I₀=i_{FAR}((n−m)Δt), and I_{—1}=i_{FAR}((n−m−1)Δt). It can be shown that the linear interpolation is an order one O(Δt) numerical process; that is, as the time step Δt approaches zero, the error becomes proportional to 1/Δt. For more information regarding linear interpolation, reference may be had to J. A. Gutierrez-Robles, L. A. Snider, J. L. Naredo and O. Ramos-Learios, “An investigation of interpolation methods applied in transmission line models for EMT analysis” International Conference on Power System Transients (2011).

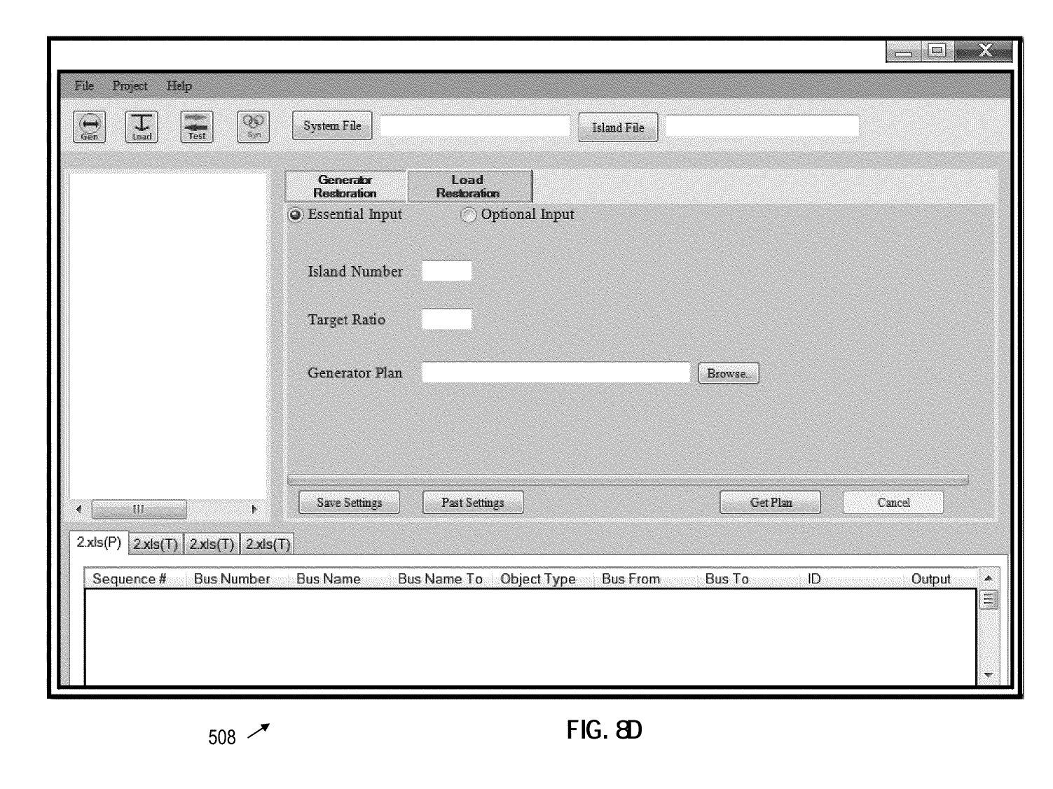

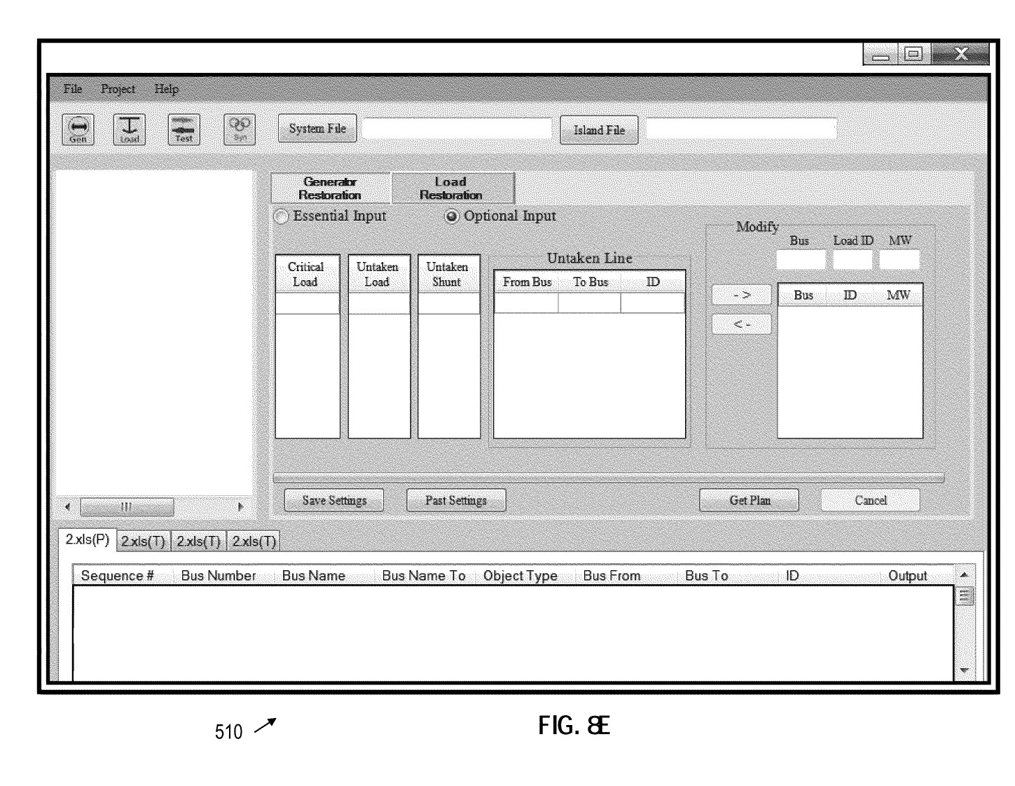

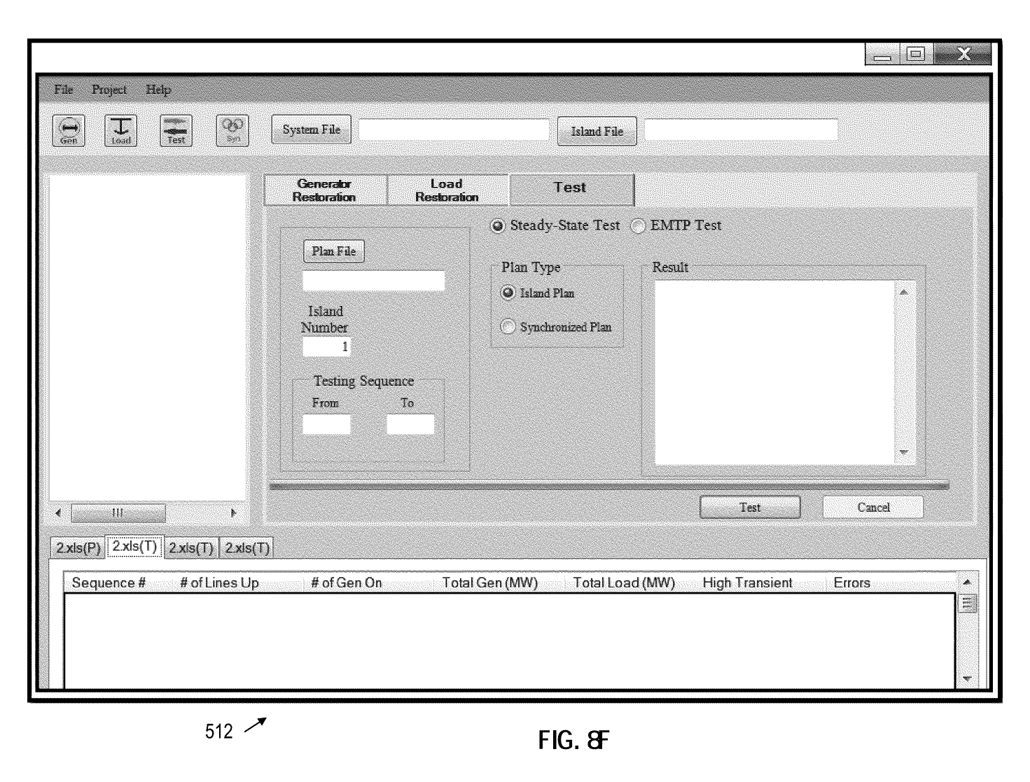

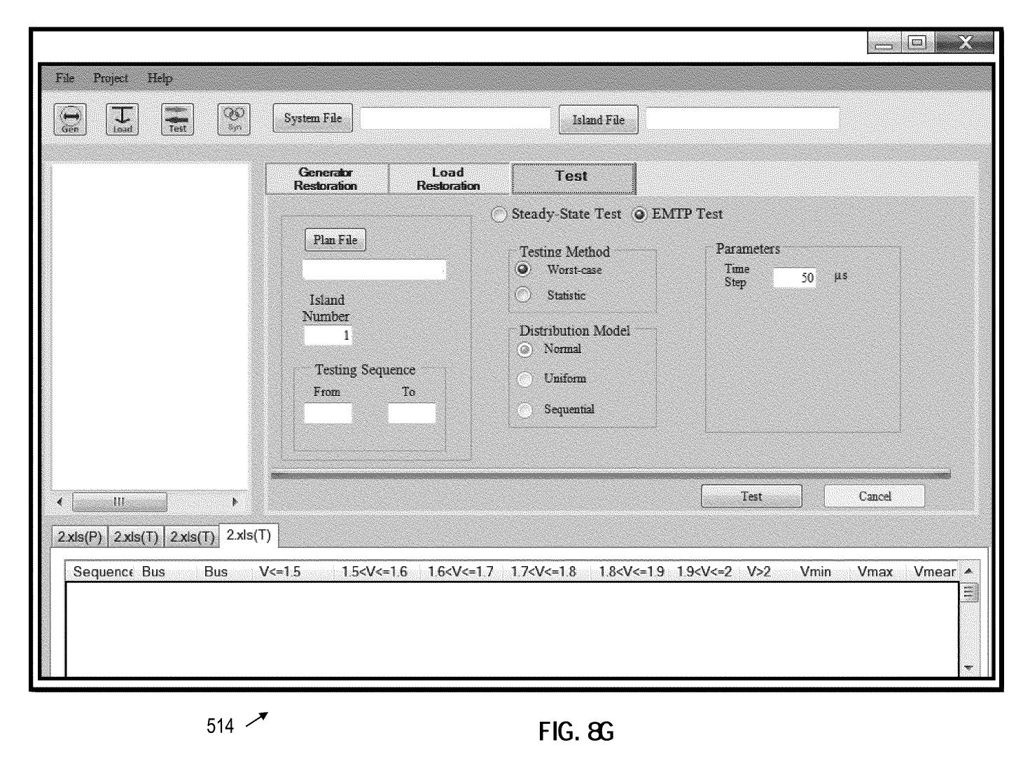

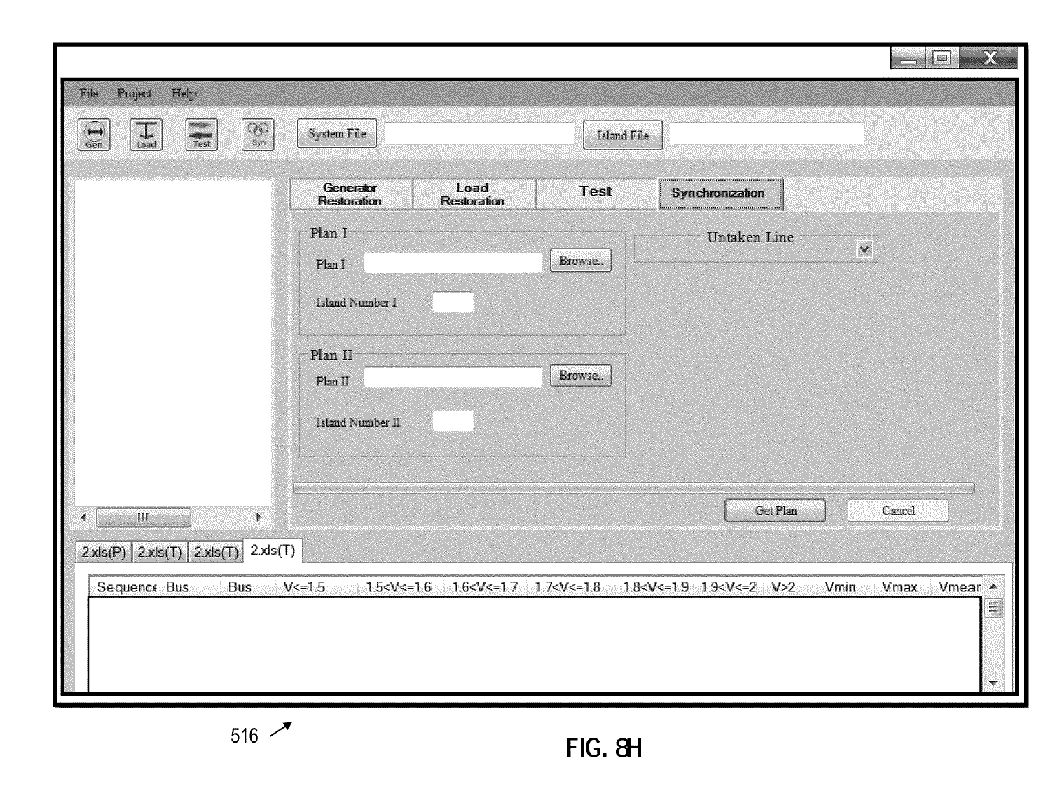

FIGS. 8A-8H show screenshots related to power restoration simulation software in accordance with an embodiment of the disclosure. In FIG. 8A, screenshot 502 shows tabs, buttons, or entry windows to enter various input parameters for generator restoration operations of the power restoration simulation application 210. For example, the input parameters may correspond to the following examples:
System File: system information including bus, generator, load and branch
Island File: bus number index in each island (subsystem) (result from sectionalization)
Essential Input:
   Island Number: the island number of the system for generator restoration
   Priority:
      Distance: the generators near black-start units are prior to be energized
      Capacity: the generators with larger minimum output are prior to be energized
   Generate New Path Mode:
      Starting Point: Staring point of the path
      Ending Point: Ending point of the path
   Modify Existing Path Mode:
      Starting Point: Starting point of the path
      Ending Point: Ending point of the path
   BS Units: black-start units
Optional Input: (shown in screenshot 504 of FIG. 8B)
   Load Ratio: the ratio of peak real power demand at load buses available for generator restoration (e.g., a value from 0 to 1)
   Critical Bus: high-priority bus to be energized
   Critical Generator: high-priority generator to be energized
   Generator Sequences: restoration sequence provided by user
   Untaken Generator: unavailable/unused generators during generator restoration
   Untaken Load: unavailable/unused loads during generator restoration
   Untaken Shunt: unavailable/unused shunts during generator restoration
   Untaken Line: unavailable/unused branches during generator restoration
Special Input: (shown in screenshot 506 of FIG. 8C)
   Generator: a selected generator to be energized
   Untaken Load: unavailable/unused loads when energizing the selected generator
   Untaken Line: unavailable/unused lines when energizing the selected generator

In FIG. 8D, screenshot 508 shows tabs, buttons, or entry windows to enter various input parameters for load restoration operations of the power restoration simulation application 210. For example, the input parameters may correspond to the following examples:
Essential Input:
   Island Number: the island number of the system for load restoration
   Target Ratio: target ratio of load to be energized in load restoration
   Generator Plan: a successful generator restoration plan
Optional Input: (shown in screenshot 510 of FIG. 8E)
   Critical Load: high-priority load to be energized
   Untaken Load: unavailable/unused generators during load restoration
   Untaken Shunt: unavailable/unused shunts during load restoration
   Untaken Line: unavailable/unused branches during load restoration
   Modify: modify bus, load ID, or peak real power demand

In FIGS. 8F and 8G, screenshots 512 and 514 shows tabs, buttons, or entry windows to enter various input parameters for test operations of the power restoration simulation application 210. For example, the input parameters may correspond to the following examples:
Steady-State Test:
   Plan File: generator/load/island restoration plan
   Island Number: the island number for plan test
   Plan Type:
      Island Plan: restoration plan for a single island
      Synchronized Plan: restoration plan for multiple islands
   Testing Sequence: test part of the restoration plan
   Result: steady-state test result
EMTP (transient) Test:
   Plan File: generator/load/island restoration plan
   Island Number: the island number for plan test
   Parameters:
      Time Step: the window (Δt) used for the transient test
   Testing Method:
      Worst-case: switch closes at the voltage peak
      Statistic: switch closes randomly under a given distribution
         Normal: normal distribution for statistic switching
         Uniform: uniform distribution for statistic switching
         Sequential: switch closes with the same time interval within a period
   Testing Sequence: test part of the restoration plan

In screenshot 514, the results of the transient test may be displayed in a table or spreadsheet format. For example, screenshot 514 shows a sequence column, a bus number column, a bus name column, a first voltage range column (less than 1.5 volts), a second voltage range column (between 1.5 up to 1.6 volts), a third voltage range column (between 1.6 up to 1.7 volts), a fourth voltage range column (between 1.7 up to 1.8 volts), a fifth voltage range column (between 1.8 up to 1.9 volts), a sixth voltage range column (between 1.9 up to 2.0 volts), a seventh voltage range column (greater than 2.0 volts), a minimum voltage column, a maximum voltage column, and a mean voltage column. Such columns are populated with transient test result data. If more than one transient test is performed, the transient test results may be available by selecting different tabs to facilitate review and analysis of the different transient test results.

In FIG. 8H, screenshot 516 shows tabs, buttons, or entry windows to enter various input parameters for synchronization operations of the power restoration simulation application 210. For example, the input parameters may correspond to the following examples:
Plan I:
   Island Number 1: island number for Plan I
Plan II:
   Island Number 2: island number for Plan II
Untaken Line: unavailable/unused line during synchronization

As desired, a user may switch between different screens by selecting respective buttons or tabs. In this manner, the features of the power restoration simulation application 210 can be accessed, updated, results reviewed, etc. While specific information is not shown, file directory information may be displayed as desired. Further, File menu, Project menu, and Help menu options are available. Example File menu features include: generating system file from PowerWorld file, and generating an island file from a system file. Example Project menu features include setting maximum simulation time. Example Help menu features include software information and user manual.

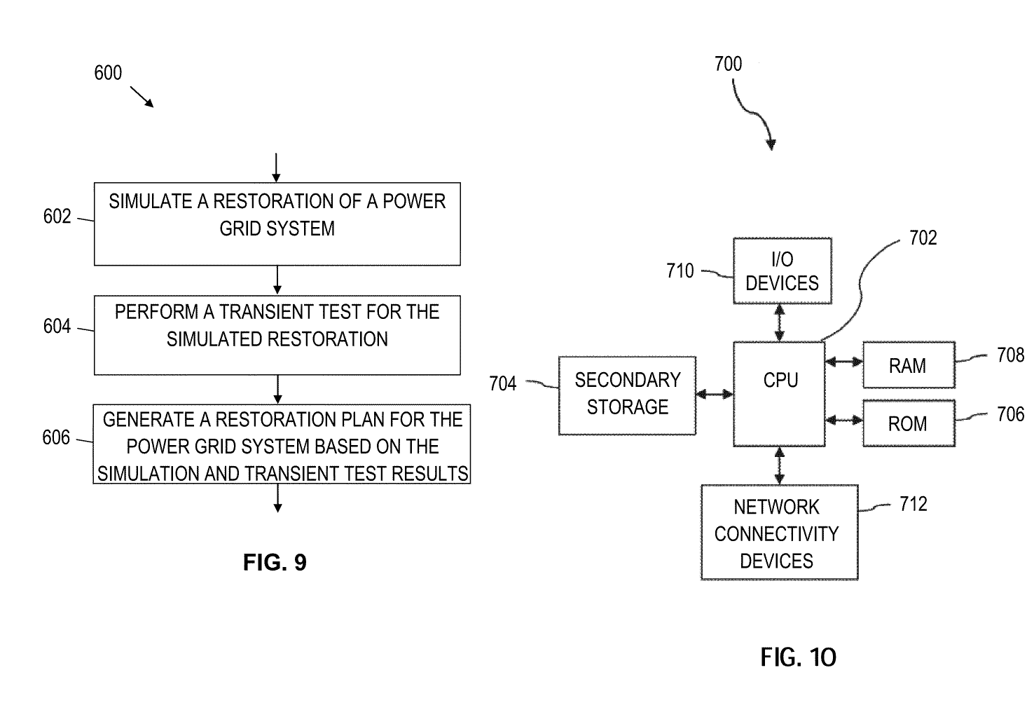

FIG. 9 is a flowchart showing an illustrative power restoration planning method 600. The method 600 may be performed, for example, by the computer system 200 of FIG. 2 and/or other computing components. As shown, the method 600 comprises simulating a restoration of a power grid system at block 602. At block 604, a transient test is performed for the simulated restoration. Various transient test options are possible as described herein. At block 606, a restoration plan is generated for the power grid system based on the simulation and the transient test results. As an example, a user may use the restoration plan, including the transient test results, to make decisions regarding how to restore power after a black-out. Further, changes to components of a power grid systems and/or connections between components may be based at least in part on a restoration plan, including the transient test results, provided by method 600.

In at least some embodiments, performing the transient test as in block 604 comprises performing an initialization stage that uses steady-state results from power flow in a previous restoration step to determine initial voltage and current for a transient value calculation. Further, performing the transient test as in block 604 may comprise performing a transient model creation stage that creates transient models based on power grid system data obtained for a steady-state analysis. Further, performing the transient test as in block 604 may comprise performing a transient model deployment stage that calculates transient voltages and currents for the power grid system data using transient models obtained from the transient model creation stage.

Further, in at least some embodiments, performing the transient test as in block 604 may comprise dividing a power grid system into subsystems and independently applying a transient analysis to each subsystem. In some cases, linear equivalence is used to represent subsystems that are already restored and stabilized. Further, the subsystems may be identified using Relative Electrical Distance (RED) analysis.

Further, in at least some embodiments, performing the transient test as in block 604 may comprise simulating closure of a switch of the power grid system at a voltage peak. Further, performing the transient test as in block 604 may comprise simulating closure of a switch of the power grid system randomly under a predetermined distribution. Further, performing the transient test as in block 604 may comprise using a short transmission line model and a long transmission line model. Further, performing the transient test as in block 604 may comprise using linear interpolation. Further, performing the transient test as in block 604 may comprise determining an electrical distance based on a generation shift factor, a power transfer distribution factor, and a line impedance.

FIG. 10 is a block diagram showing illustrative component of a computer system 700. The computer system 700 may correspond to computer system 200 or similar computing devices capable of executing instructions to perform power restoration simulation, including transient test operations, as described herein. The computer system 700 may correspond to, for example, components of the computer system 200 described herein.

As shown, the computer system 700 includes a processor 702 (which may be referred to as a central processor unit or CPU) that is in communication with memory devices including secondary storage 704, read only memory (ROM) 706, random access memory (RAM) 708, input/output (I/O) devices 710, and network connectivity devices 712. The processor 702 may be implemented as one or more CPU chips.

It is understood that by programming and/or loading executable instructions onto the computer system 700, at least one of the CPU 702, the RAM 708, and the ROM 706 are changed, transforming the computer system 700 in part into a particular machine or apparatus having the novel functionality taught by the present disclosure. In the electrical engineering and software engineering arts functionality that can be implemented by loading executable software into a computer can be converted to a hardware implementation by well-known design rules. Decisions between implementing a concept in software versus hardware typically hinge on considerations of stability of the design and numbers of units to be produced rather than any issues involved in translating from the software domain to the hardware domain. For example, a design that is still subject to frequent change may be implemented in software, because re-spinning a hardware implementation is more expensive than re-spinning a software design. Meanwhile, a design that is stable that will be produced in large volume may be preferred to be implemented in hardware, for example in an application specific integrated circuit (ASIC), because for large production runs the hardware implementation may be less expensive than the software implementation. Often a design may be developed and tested in a software form and later transformed, by well-known design rules, to an equivalent hardware implementation in an application specific integrated circuit that hardwires the instructions of the software. In the same manner as a machine controlled by a new ASIC is a particular machine or apparatus, likewise a computer that has been programmed and/or loaded with executable instructions may be viewed as a particular machine or apparatus.

The secondary storage 704 may be comprised of one or more disk drives or tape drives and is used for non-volatile storage of data and as an over-flow data storage device if RAM 708 is not large enough to hold all working data. Secondary storage 704 may be used to store programs which are loaded into RAM 708 when such programs are selected for execution. The ROM 706 is used to store instructions and perhaps data which are read during program execution. ROM 706 is a non-volatile memory device which typically has a small memory capacity relative to the larger memory capacity of secondary storage 704. The RAM 708 is used to store volatile data and perhaps to store instructions. Access to both ROM 706 and RAM 708 is typically faster than to secondary storage 704. The secondary storage 704, the RAM 708, and/or the ROM 706 may be referred to in some contexts as computer readable storage media and/or non-transitory computer readable media.

I/O devices 710 may include printers, video monitors, liquid crystal displays (LCDs), touch screen displays, keyboards, keypads, switches, dials, mice, track balls, voice recognizers, card readers, paper tape readers, or other well-known input devices.

The network connectivity devices 712 may take the form of modems, modem banks, Ethernet cards, universal serial bus (USB) interface cards, serial interfaces, token ring cards, fiber distributed data interface (FDDI) cards, wireless local area network (WLAN) cards, radio transceiver cards such as code division multiple access (CDMA), global system for mobile communications (GSM), long-term evolution (LTE), worldwide interoperability for microwave access (WiMAX), and/or other air interface protocol radio transceiver cards, and other well-known network devices. These network connectivity devices 712 may enable the processor 1202 to communicate with the Internet or one or more intranets. With such a network connection, it is contemplated that the processor 702 might receive information from the network, or might output information to the network in the course of performing the above-described method steps. Such information, which is often represented as a sequence of instructions to be executed using processor 702, may be received from and outputted to the network, for example, in the form of a computer data signal embodied in a carrier wave.

Such information, which may include data or instructions to be executed using processor 702 for example, may be received from and outputted to the network, for example, in the form of a computer data baseband signal or signal embodied in a carrier wave. The baseband signal or signal embedded in the carrier wave, or other types of signals currently used or hereafter developed, may be generated according to several methods known to one skilled in the art. The baseband signal and/or signal embedded in the carrier wave may be referred to in some contexts as a transitory signal.

The processor 702 executes instructions, codes, computer programs, scripts which it accesses from hard disk, floppy disk, optical disk (these various disk based systems may all be considered secondary storage 704), ROM 706, RAM 708, or the network connectivity devices 712. While only one processor 702 is shown, multiple processors may be present. Thus, while instructions may be discussed as executed by a processor, the instructions may be executed simultaneously, serially, or otherwise executed by one or multiple processors. Instructions, codes, computer programs, scripts, and/or data that may be accessed from the secondary storage 704, for example, hard drives, floppy disks, optical disks, and/or other device, the ROM 706, and/or the RAM 708 may be referred to in some contexts as non-transitory instructions and/or non-transitory information.

In an embodiment, the computer system 700 may comprise two or more computers in communication with each other that collaborate to perform a task. For example, but not by way of limitation, an application may be partitioned in such a way as to permit concurrent and/or parallel processing of the instructions of the application. Alternatively, the data processed by the application may be partitioned in such a way as to permit concurrent and/or parallel processing of different portions of a data set by the two or more computers. In an embodiment, virtualization software may be employed by the computer system 700 to provide the functionality of a number of servers that is not directly bound to the number of computers in the computer system 1200. For example, virtualization software may provide twenty virtual servers on four physical computers. In an embodiment, the functionality disclosed above may be provided by executing the application and/or applications in a cloud computing environment. Cloud computing may comprise providing computing services via a network connection using dynamically scalable computing resources. Cloud computing may be supported, at least in part, by virtualization software. A cloud computing environment may be established by an enterprise and/or may be hired on an as-needed basis from a third party provider. Some cloud computing environments may comprise cloud computing resources owned and operated by the enterprise as well as cloud computing resources hired and/or leased from a third party provider.

In an embodiment, some or all of the power restoration simulation and planning techniques disclosed above may be provided as a computer program product. The computer program product may comprise one or more computer readable storage medium having computer usable program code embodied therein to implement the functionality disclosed above. The computer program product may comprise data structures, executable instructions, and other computer usable program code. The computer program product may be embodied in removable computer storage media and/or non-removable computer storage media. The removable computer readable storage medium may comprise, without limitation, a paper tape, a magnetic tape, magnetic disk, an optical disk, a solid state memory chip, for example analog magnetic tape, compact disk read only memory (CD-ROM) disks, floppy disks, jump drives, digital cards, multimedia cards, and others. The computer program product may be suitable for loading, by the computer system 700, at least portions of the contents of the computer program product to the secondary storage 704, to the ROM 706, to the RAM 708, and/or to other non-volatile memory and volatile memory of the computer system 700. The processor 702 may process the executable instructions and/or data structures in part by directly accessing the computer program product, for example by reading from a CD-ROM disk inserted into a disk drive peripheral of the computer system 700. Alternatively, the processor 702 may process the executable instructions and/or data structures by remotely accessing the computer program product, for example by downloading the executable instructions and/or data structures from a remote server through the network connectivity devices 712. The computer program product may comprise instructions that promote the loading and/or copying of data, data structures, files, and/or executable instructions to the secondary storage 704, to the ROM 706, to the RAM 708, and/or to other non-volatile memory and volatile memory of the computer system 700.

In some contexts, the secondary storage 704, the ROM 706, and the RAM 708 may be referred to as a non-transitory computer readable medium or a computer readable storage media. A dynamic RAM embodiment of the RAM 708, likewise, may be referred to as a non-transitory computer readable medium in that while the dynamic RAM receives electrical power and is operated in accordance with its design, for example during a period of time during which the computer 700 is turned on and operational, the dynamic RAM stores information that is written to it. Similarly, the processor 702 may comprise an internal RAM, an internal ROM, a cache memory, and/or other internal non-transitory storage blocks, sections, or components that may be referred to in some contexts as non-transitory computer readable media or computer readable storage media.

In some examples, a non-transitory computer-readable storage medium may store a program or instructions that cause the processor 702 to simulate restoration of a power grid system, to perform a transient test for the simulated restoration, and to generate a restoration plan for the power grid system based on the simulation and transient test results. In at least some embodiments, the transient test may is performed based on an initialization stage that uses steady-state results from power flow in a previous restoration step to determine initial voltage and current for a transient value calculation. Further, the transient test may be performed based on a transient model creation stage that creates transient models based on power grid system data obtained for a steady-state analysis. Further, the transient test may be performed based on a transient model deployment stage that calculates transient voltages and currents for the power grid system data using transient models obtained from the transient model creation stage.

In at least some embodiments, the transient test performed by the processor 702 includes dividing the power grid system into subsystems and independently applying a transient analysis to each subsystem. In such case, the transient test may be performed using linear equivalence to represent subsystems that are already restored and stabilized. Further, the subsystems may be identified using Relative Electrical Distance (RED) analysis.

In at least some embodiments, the transient test performed by the processor 702 is based on a simulation that closes a switch of the power grid system at a voltage peak. Alternatively, the transient test may be performed based on a simulation that closes a switch of the power grid system randomly under a predetermined distribution (e.g., a normal distribution, a uniform distribution, or a sequential distribution). Further, in at least some embodiments, the transient test performed by the processor 702 may be performed using a short transmission line model and a long transmission line model. Further, in at least some embodiments, the transient test may be performed using linear interpolation to improve efficiency. Further, in at least some embodiments, the transient test may be performed using an electrical distance computed using a generation shift factor, a power transfer distribution factor, and a line impedance.

In at least some embodiments, the processor 702 is in communication with a display such that a program or instructions, when executed, cause the processor 702 to provide a user interface on the display that enables a user to select transient test options (see e.g., FIG. 8G). Further, the instructions, when executed, may cause the processor 702 to provide a user interface on the display that enables a user to view transient test results for a restoration plan.

While several embodiments have been provided in the present disclosure, it should be understood that the disclosed systems and methods may be embodied in many other specific forms without departing from the spirit or scope of the present disclosure. The present examples are to be considered as illustrative and not restrictive, and the intention is not to be limited to the details given herein. For example, the various elements or components may be combined or integrated in another system or certain features may be omitted or not implemented.

Without limitation to other embodiments, various concepts are described herein including the following:
1. Separation concept for automated transient analysis: This concept is to separate the automated transient analysis in power system restoration planning into three processes: initialization, model creation and calculation. The objective for initialization is to determine the initial status of voltage and current for EMTP calculation. The objective for model creation is to create EMTP models automatically based on common data in steady state analysis. The objective for calculation is to calculate electromagnetic transients in the system by using nodal analysis.
2. Determination of initial status for transient analysis: the transient analysis includes an initialization process that uses steady-state results from power flow in the previous restoration step to determine initial voltage and current for transient calculations.
3. Transient model creation: the model creation process includes creating transient models automatically based on common system data in steady-state analysis.
4. Subsystem concept for transient analysis in large scale power system: a large scale power system can be divided into several subsystems and transient analysis is applied in each subsystem independently.
5. Linear equivalence for subsystems: linear equivalence is used to represent subsystems which are already restored and stabilized by linear equivalent sources to improve the efficiency of transient calculations.
6. Worst-case switching: worst-case switching refers to a test scenario in which a switch closes at the voltage peaks. It can be used for a quick transient analysis.
7. Statistical switching: statistical switching refers to a test scenario in which a switch closes randomly under a given distribution. It can be used for a detailed transient analysis.
8. Criteria for transmission line model: creating transient models involves creating two types of transmission line models for transient calculations. A short transmission line model (see FIG. 4E) is used for waves travelling less time than a given time step. A long transmission line model (see FIG. 4D) is used for waves travelling more time than a given time step.
9. Linear interpolation: transient calculations may involve using linear interpolation to remove numerical oscillation caused by trapezoidal.
10. Electrical distance (ED) concept: The ED concept can be the Absolute Electrical Distance (AED), i.e. equivalent impedance between two buses under consideration during the restoration process. ED can also be the Relative Electrical Distance (RED) between two buses under consideration during the restoration process, which is derived and normalized based on the impedance and AED.
11. ED computation: ED is computed using generation shift factor, power transfer distribution factor, and line impedance (in P.U.).
12. Subsystem identification: relative electrical distance (RED) may be used to identify subsystems in the entire system for linear equivalence.

It should be appreciated that the techniques, systems, subsystems, and methods described and illustrated in the various embodiments as discrete or separate may be combined or integrated with other systems, modules, techniques, or methods without departing from the scope of the present disclosure. Other items shown or discussed as directly coupled or communicating with each other may be indirectly coupled or communicating through some interface, device, or intermediate component, whether electrically, mechanically, or otherwise. Other examples of changes, substitutions, and alterations are ascertainable by one skilled in the art and could be made without departing from the spirit and scope disclosed herein.

Numerous variations and modifications will become apparent to those skilled in the art once the above disclosure is fully appreciated. It is intended that the following claims be interpreted to embrace all such variations and modifications.

What is claimed is:

1. A computer system, comprising:
at least one processor; and
a storage device coupled to the at least one processor and storing instructions that, when executed, causes the at least one processor to:
simulate restoration of a power grid system;
perform a transient test for the simulated restoration; and
generate a restoration plan for the power grid system based on the simulation and transient test results.

2. The computer system of claim 1, wherein the transient test is performed based on:
an initialization stage that uses steady-state results from power flow in a previous restoration step to determine initial voltage and current for a transient value calculation;
a transient model creation stage that creates transient models based on power grid system data obtained for a steady-state analysis; and
a transient model deployment stage that calculates transient voltages and currents for the power grid system data using transient models obtained from the transient model creation stage.

3. The computer system of claim 1, wherein the transient test is performed by dividing the power grid system into subsystems and independently applying a transient analysis to each subsystem.

4. The computer system of claim 3, wherein the transient test is performed using linear equivalence to represent subsystems that are already restored and stabilized.

5. The computer system of claim 3, wherein the subsystems are identified using Relative Electrical Distance (RED) analysis.

6. The computer system of claim 1, wherein the transient test is performed based on a simulation that closes a switch of the power grid system at a voltage peak.

7. The computer system of claim 1, wherein the transient test is performed based on a simulation that closes a switch of the power grid system randomly under a predetermined distribution.

8. The computer system of claim 1, wherein the transient test is performed using a short transmission line model and a long transmission line model.

9. The computer system of claim 1, wherein the transient test is performed using linear interpolation.

10. The computer system of claim 1, wherein the transient test is performed using an electrical distance computed using a generation shift factor, a power transfer distribution factor, and a line impedance.

11. The computer system of claim 1, further comprising a display in communication with the at least one processor, wherein the instructions, when executed, cause the at least one processor to provide a user interface on the display that enables a user to select transient test options.

12. The computer system of claim 1, further comprising a display in communication with the at least one processor, wherein the instructions, when executed, cause the at least one processor to provide a user interface on the display that enables a user to view transient test results for a restoration plan.

13. A method, comprising:
simulating, by at least one processor, a restoration of a power grid system;
performing, by the at least one processor, a transient test for the simulated restoration; and
generating, by the at least one processor, a restoration plan for the power grid system based on the simulation and transient test results.

14. The method of claim 13, wherein performing the transient test comprises:
performing an initialization stage that uses steady-state results from power flow in a previous restoration step to determine initial voltage and current for a transient value calculation;
performing a transient model creation stage that creates transient models based on power grid system data obtained for a steady-state analysis; and
performing a transient model deployment stage that calculates transient voltages and currents for the power grid system data using transient models obtained from the transient model creation stage.

15. The method of claim 13, wherein performing the transient test comprises dividing the power grid system into subsystems and independently applying a transient analysis to each subsystem, wherein linear equivalence is used to represent subsystems that are already restored and stabilized, and wherein the subsystems are identified using Relative Electrical Distance (RED) analysis.

16. The method of claim 13, wherein performing the transient test comprises simulating closure of a switch of the power grid system at a voltage peak.

17. The method of claim 13, wherein performing the transient test comprises simulating closure of a switch of the power grid system randomly under a predetermined distribution.

18. The method of claim 13, wherein performing the transient test comprises using a short transmission line model and a long transmission line model.

19. The method of claim 13, wherein performing the transient test comprises using linear interpolation.

20. The method of claim 13, wherein performing the transient test comprises determining an electrical distance based on a generation shift factor, a power transfer distribution factor, and a line impedance.
